(19) United States
(12) Patent Application Publication
(10) Pub. No.: US 2010/0176002 A1
(43) Pub. Date: Jul. 15, 2010

(54) METHOD OF FORMING A COLORFUL COATING ON A TRANSPARENT PLASTIC ARTICLE

(76) Inventor: Yi-Ren Ye, Guangdong (CN)

Correspondence Address: Dr. BANGER SHIA;Patent Office of Bang Shia, 102 Lindencrest Ct., Sugar Land, TX, 77479-5201, US

(21) Appl. No.: 12/664,058

(22) PCT Filed: Jun. 20, 2007
(86) PCT No.: PCT/CN2007/001924

§ 371 Date: Dec. 10, 2009

(51) Int. Cl. C25D 5/00; C23C 14/02; C23C 14/22; B05D 1/18; B05D 5/06; C25D 9/00

(52) U.S. Cl. 205/183

(57) ABSTRACT

A method for forming a colorful coating on a transparent plastic article comprises following steps: dipping a transparent plastic article into liquid coating bath for dyeing, removing the dyed plastic article from the coating bath and then washing and baking it, and subsequently vacuum depositing a metallic film on the plastic article. As a result, there is a colorful coating formed on the transparent plastic article.

### BACKGROUND OF THE INVENTION

1. Field of the Invention

The present invention relates to a method for forming a colorful coating on a transparent plastic article, and the plastic article is used extensively in the fields of manufacturing lenses, press keys or viewing windows of communication/electronic products.

2. Description of the Prior Art

At present, most electronic/communication products (such as lenses, press buttons and viewing windows of mobile phones/personal phone systems), home electric appliances (such as window panels, press key panels, and decorative panels) select plastic articles as the raw materials for the manufacture. Each of the aforementioned products made by the plastic article is generally coated with dyes directly to produce a colorful coating on the product, and thus dusts may be adhered onto the coating easily to produce a large quantity of defectives during the manufacturing process, or a colored plastic sheet is used directly to produce a colorful product. As a result, the material cannot be recycled or reused easily, and raw materials are wasted to incur a higher manufacturing cost.

### SUMMARY OF THE INVENTION

The primary object of the present invention is to overcome the shortcomings of the prior art by providing a method of forming a colorful coating on a transparent plastic article.

To achieve the aforementioned objective, the present invention provides a method for forming a colorful coating on a transparent plastic article comprising the steps of: dipping a transparent plastic article into liquid coating bath for dyeing; removing the dyed plastic article from the coating bath and then washing and baking it; and subsequently vacuum depositing a metallic film on the plastic article. As a result, there is a colorful coating with a metallic texture formed on the transparent plastic article.

The film can be a metallic film or a non-metallic film.

The plastic article is a plastic sheet.

The plastic article is a plastic injection article. The plastic article is dyed, washed and baked, and then a primer is coated onto a pre-electroplated surface, and finally a metallic film is vacuum electroplated onto the primer.

The advantage of the present invention resides on that the transparent plastic article is dyed, washed, baked, and finally coated with a colorful coating in the electroplating process to overcome the shortcomings of the prior art that coats dyes directly or using a color plastic article, and the colorful coating also provides a good decorative effect to the product.

### BRIEF DESCRIPTION OF THE DRAWINGS

FIG. 1 shows a first preferred embodiment of the present invention; and

FIG. 2 shows a second preferred embodiment of the present invention.

### DETAILED DESCRIPTION OF THE PREFERRED EMBODIMENTS

Embodiments of the present invention will now be described, by way of example only, with reference to the accompanying drawings.

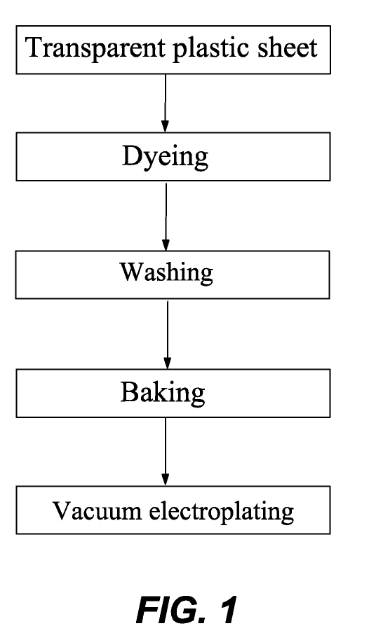

With reference to FIG. 1 for a method for forming a colorful coating on a transparent plastic article in accordance with a first preferred embodiment of the present invention, the plastic article is made of a transparent plastic sheet, and the transparent plastic article is dipped into a liquid coating for dyeing, and then the transparent plastic article is removed, washed and baked, and finally a metallic film is vacuum electroplated onto the plastic sheet to form a colorful coating with a metal texture on the transparent plastic sheet.

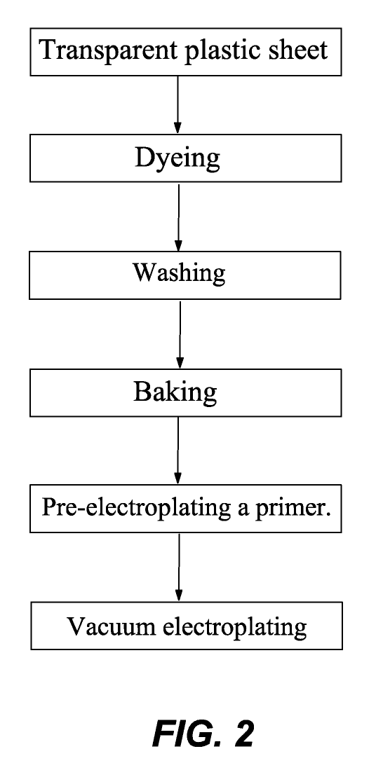

With reference to FIG. 2 for a method for forming a colorful coating on a transparent plastic article in accordance with a second preferred embodiment of the present invention, the plastic article is a transparent plastic injection article, and the transparent plastic injection article is dipped into a liquid coating for dyeing, and then the transparent plastic injection article is removed, washed and baked, and a primer is coated onto a pre-electroplating surface, and finally a metallic film is vacuum deposited onto the primer to form a colorful coating with a metallic texture on the transparent plastic injection article. Of course, the process of coating the primer is not absolutely necessary.

In summation of the description of the aforementioned two preferred embodiments, the key points of the present invention resides on that the transparent plastic article is dyed, washed, baked, and finally coated with a colorful coating in the electroplating process to overcome the shortcomings of the prior art that coats dyes directly or using a color plastic article, and the colorful coating also provides a good decorative effect to the product. The metallic film vacuum electroplated onto the plastic article can also be a non-metallic film, and a conventional dyeing technique can also be used for coating different dyes onto the transparent plastic article.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A method for forming a colorful coating on a transparent plastic article, comprising the steps of:
dipping a transparent plastic article into a liquid coating bath for dyeing:
removing the dyed plastic article from the coating bath:
washing and baking the dyed plastic article; and
vacuum depositing a metallic film on the plastic article to form a color coating with a metallic texture on the transparent plastic article.

2. The method for forming a colorful coating on a transparent plastic article as claimed in claim 1, wherein the film is a metallic film or a non-metallic film.

3. The method for forming a colorful coating on a transparent plastic article of as claimed in claim 1 or 2, wherein the plastic article is a plastic sheet.

4. The method for forming a colorful coating on a transparent plastic article as claimed in claim 1 or 2, wherein the plastic article is a plastic injection article.

5. The method for forming a colorful coating on a transparent plastic article as claimed in claim 3, wherein the plastic injection article is dyed, washed, baked, and coated with a primer onto a pre-electroplating surface, and finally a metallic film is vacuum deposited onto the primer.
